(19) United States
(12) Patent Application Publication
(10) Pub. No.: US 2002/0142613 A1
(43) Pub. Date: Oct. 3, 2002

(54) Method for controlling etching depth

(76) Inventors: Ching-Hung Fu, Hsinchu (TW); Nien-Yu Tsai, Hsinchu (TW)

Correspondence Address: VOLPE AND KOENIG, P.C., SUITE 400, ONE PENN CENTER, 1617 JOHN F. KENNEDY BOULEVARD, PHILADELPHIA, PA, 19103, US

(21) Appl. No.: 09/824,476

(22) Filed: Apr. 2, 2001

(51) Int. Cl. H01L 21/302; H01L 21/461

(52) U.S. Cl. 438/719

(57) ABSTRACT

A method for controlling an etching depth in a semiconductor fabricating process is provided. The method includes steps of providing a substrate having a first reflecting region and a second reflecting region, illuminating the first reflecting region and the second reflecting region with a coherence light having a wavelength λ to generate an interference, performing a first etching on the second reflecting region to generate a height difference between the first reflecting region and the second reflecting region, wherein the interference intensity is changed with the first etching, and performing a second etching on the second reflecting region for a specific period of time to make the etching depth as the height difference when the interference intensity is changed to a relative extreme value.

### FIELD OF THE INVENTION

The present invention relates to a method for controlling an etching method, and more particularly to a method for controlling an etching depth in a semiconductor fabricating process.

### BACKGROUND OF THE INVENTION

Presently, the etching technique on a wafer is widely used in fabricating a deep trench capacitor for a dynamic random access memory (DRAM) device. Please refer to FIGS. 1(a) to (g). A silicon nitride layer 11 and a photoresisting layer 12 are formed in sequence on a silicon substrate 10. A plurality of openings 13 are formed on the photoresisting layer 12 by a photolithography process, as can be seen in FIG. 1(a). The exposed portions of the silicon nitride layer 11 in the openings 13 are etched in sequence to form openings of a mask shown in FIG. 1(b). Subsequently, the residual photoresisting layer 12 is stripped, and the silicon substrate 10 is etched through the openings of the mask to form a deep trench structure 14 shown in FIGS. 1(c) and (d).

For fabricating the capacitor, a polysilicon layer 15 is formed on the silicon substrate 10 shown in FIG. 1(e). Referring to FIG. 1(f) the polysilicon layer 15 is etched back until the silicon nitride layer 11 is exposed. The polysilicon layer 15 is further etched to form the structure shown in FIG. 1(g).

In the prior art, for controlling the etching depth d of the structure shown in FIG. 1(g) to be uniform on each silicon wafer, reflecting regions 161 and 162 shown in FIG. 1(f) are illuminated by coherence light. The interference is generated by the reflecting light from the reflecting regions 161 and 162. The interference intensity is changed with the etching depth. The interference intensity is detected by an interferometer and represented with an oscillogram. Hence, the time point to stop the etching could be calculated.

Please refer to FIG. 2. According to the interference theory, the time difference Δt between the wave crest and the wave trough could be derived from the time needed by a quarter coherence light wavelength λ increase of the etching depth, and the etching rate (ER) could be calculated as λ/(4×Δt). Hence, the time T needed by etching a depth difference Δd is Δd/ER. The etching time T is used for controlling the etching depth d.

However, in the foresaid fabricating process, the etching back step on the polysilicon layer 15 could not ensure that the structure shown in FIG. 1(f) is uniform. The height difference between the reflecting region 161 and the reflecting region 162 could not maintain constant before etching the polysilicon in the deep trench structure 14. The etching time T is only used for etching a constant depth difference Δd. The original height of the polysilicon layer in the deep trench structure 14 could be different on each wafer. Furthermore, the etching rate could not actually be a constant. Thus, the etching depth d could not be controlled to be uniform in the prior art.

In order to overcome the foresaid problems, the present invention provide a method for controlling the etching depth in a semiconductor fabricating process.

### SUMMARY OF THE INVENTION

It is an object of the present invention to provide a method for controlling an etching depth in a semiconductor fabricating process.

In accordance with the present invention, the method includes steps of providing a substrate having a first reflecting region and a second reflecting region, illuminating the first reflecting region and the second reflecting region with a coherence light having wavelength λ to generate an interference, performing a first etching on the second reflecting region to generate a height difference between the first reflecting region and the second reflecting region, wherein the interference intensity is changed with the first etching step, and performing a second etching on the second reflecting region for a specific period of time to make the etching depth as the height difference when the interference intensity is changed to a relative extreme value.

Preferably, the relative extreme value is less than the height difference, wherein the difference between the relative extreme value and the height difference is one of a value equal to λ/4 and a value less than λ/4.

Preferably, the substrate is a silicon substrate. The first reflecting region and the second reflecting region are made of silicon and polysilicon, respectively.

Preferably, the coherence light is emitted from a mercury lamp and a wavelength thereof is 2,537 angstrom.

The coherence light could be a laser having an adjustable wavelength.

Preferably, each of the first etching and the second etching is an anisotropic dry etching.

In addition, the relative extreme value is located at one of a wave crest and a wave trough of the interference.

Furthermore, the specific period of time is determined by steps of selecting two adjacent relative extreme values in the first etching and the second etching to obtain a time difference Δt, and obtaining etching rate (ER) as λ/(4×Δt), and adding up a total number n of relative extreme values of the interference from beginning of the first and second etching to a time point which the relative extreme value is obtained, and obtaining the height difference between the first reflecting region and the second reflecting region as n λ/4 and the period of time as (the height difference −nλ/4)/ER.

Preferably, the first reflecting region and the second reflecting region are made of silicon and metal, respectively.

In addition, a variant difference of an original height difference between the first reflecting region and the second reflecting region is one of a value equal to λ/4 and a value less than λ/4.

It is another object of the present invention to provide a method for controlling an etching depth in a semiconductor fabricating process.

In accordance with the present invention, the method includes steps of providing a substrate having a first reflecting region and a second reflecting region, performing an etching on the second reflecting region to generate a height difference between the first reflecting region and the second reflecting region, selecting a coherence light having a wavelength λ to make the height difference be multiple of λ/4, and illuminating the first reflecting region and the second reflecting region with the coherence light to generate an interference, wherein the interference intensity is changed with the etching step, and stopping the etching performance to make the etching depth as the height difference when the interference intensity is changed to a relative extreme value.

Preferably, the substrate is a silicon substrate.

Preferably, the first reflecting region and the second reflecting region are made of silicon and polysilicon, respectively.

The coherence light could be a laser having an adjustable wavelength.

Preferably, the etching is an anisotropic dry etching.

In addition, the relative extreme value is located at one of a wave crest and a wave trough of the interference.

The etching performance is stopped when a total number of the relative extreme values of the interference are added up to n, and the height difference nλ/4 is obtained as the etching depth.

Preferably, the first reflecting region and the second reflecting region are made of silicon and metal, respectively.

In addition, a variant difference of an original height difference between the first reflecting region and the second reflecting region is one of a value equal to λ/4 and a value less than λ/4.

The present invention may best be understood through the following descriptions with reference to the accompanying drawings, in which:

### BRIEF DESCRIPTION OF THE DRAWINGS

FIGS. 1(a) to (g) are schematic views showing a partial technique of fabricating a deep trench capacitor according to the prior art;

FIG. 2 is a diagram showing the relationship between the interference intensity and the etching time according to the prior art;

FIGS. 3(a) and (b) are schematic views showing the intermediate product in fabricating a deep trench capacitor according to the preferred embodiment of the present invention; and

FIG. 4 is a diagram showing the relationship between the interference intensity and the etching time according to the preferred embodiment of the present invention.

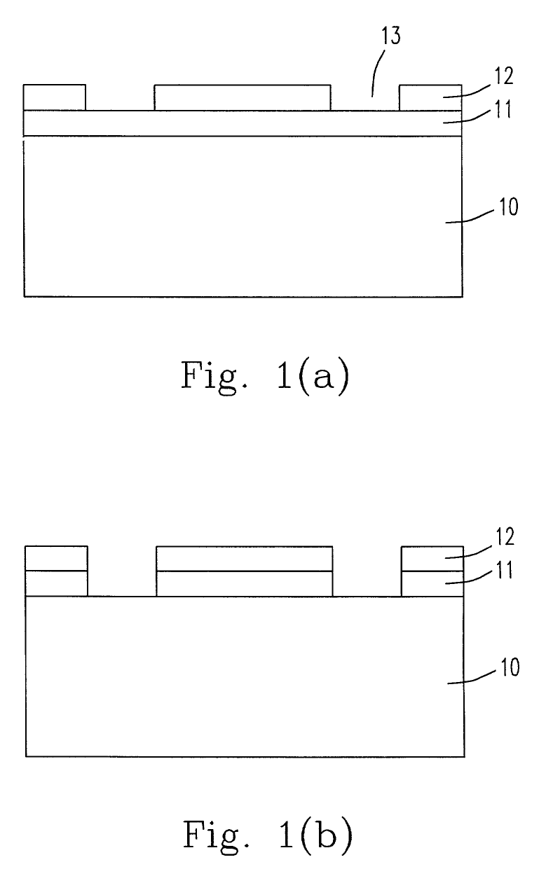

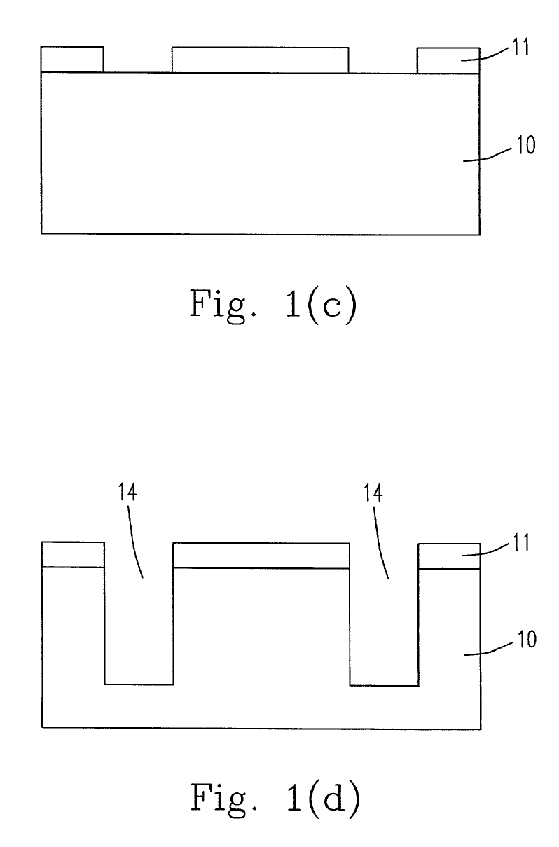

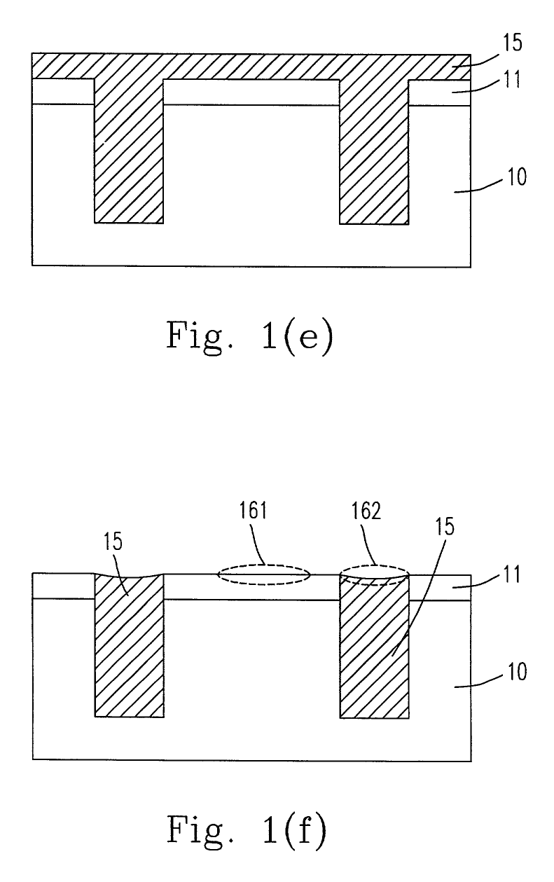

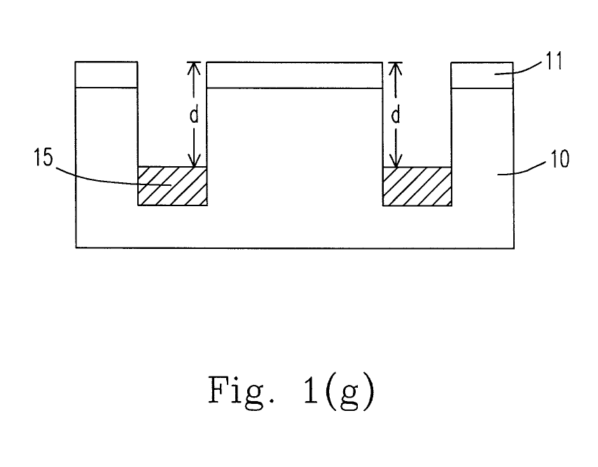

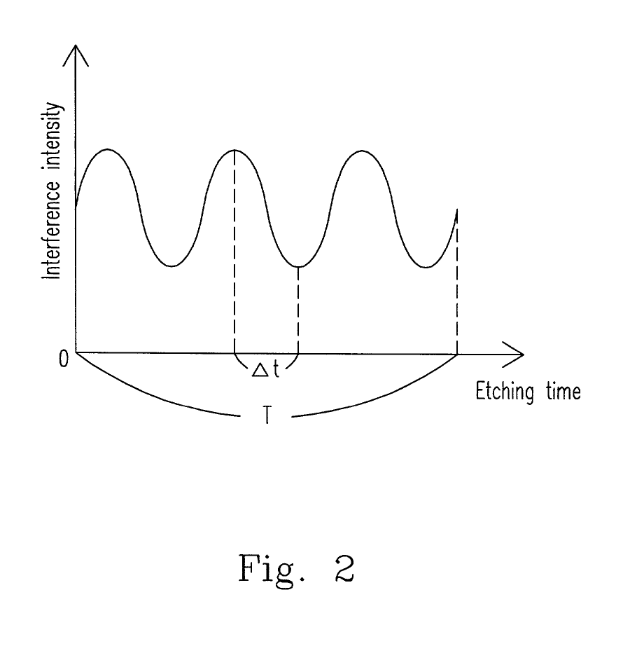

### DETAILED DESCRIPTION OF THE PREFERRED EMBODIMENTS

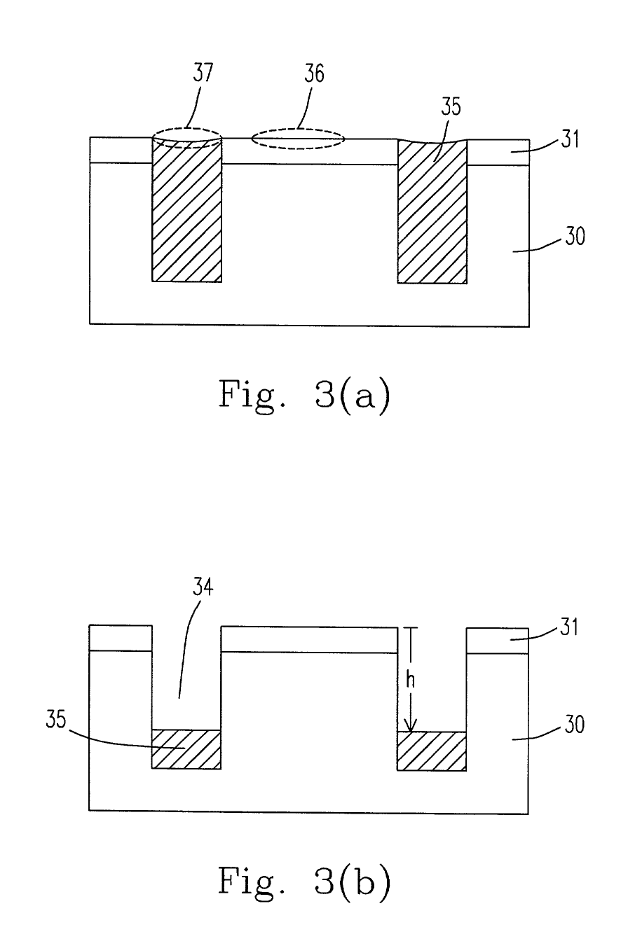

Please refer to FIGS. 3(a) and (b). The polysilicon 35 in a deep trench structure 34 is etched by an anisotropic dry etching. A first reflecting region 36 of a silicon substrate 30 in the periphery of the deep trench structure 34 and a second reflecting region 37 of the polysilicon 35 in the deep trench structure 34 are illuminated by coherence light having a wavelength λ. The coherence light having 2,537 angstrom wavelength could be emitted from a mercury lamp and the silicon nitride layer 31 could be considered as transparent. The interference is formed by the reflecting light from the first reflecting region 36 and the reflecting region 37.

The polysilicon 35 in the second reflecting region 37 is etched. Then, the height difference between the surface of the silicon substrate 30 in the first reflecting region 36 and the surface of the polysilicon 35 in the second reflecting region 37 is increased.

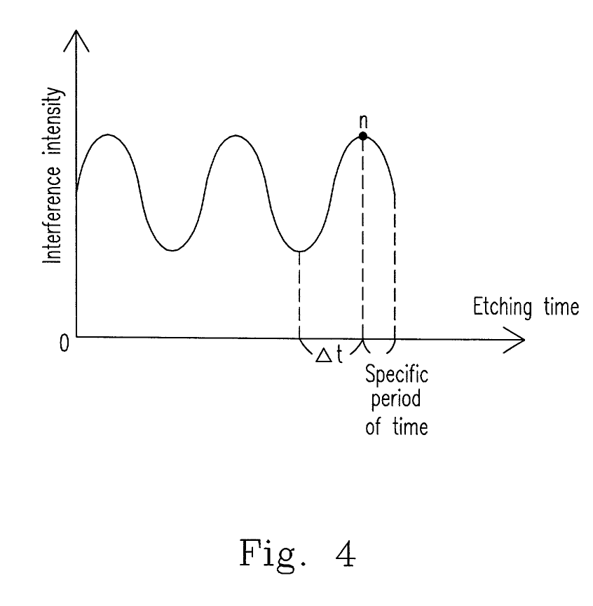

The interference intensity is changed with the etching time. The interference intensity is detected by a interferometer and represented with an oscillogram shown in FIG. 4.

The wave crest and the adjacent wave trough are represented a quarter coherence light wavelength λ increase of the height difference between the first reflecting region 36 and the second reflecting region 37. A relative extreme value (i.e. the wave crest or the wave trough) is selected. The total relative extreme values of the interference intensity from the beginning of the etching performance to the selected relative extreme value are added up. The height difference between the first reflecting region 36 and the second reflecting region 37 is (n×λ/4)+k, wherein k is the etching depth representing the phase difference φ between the initial phase and the first relative extreme value i.e. the wave crest or the wave trough. Thus, k value is φλ/4π. The difference between the height difference, i.e. (n×λ/4)+k, and the selected height difference h is h−((n×λ/4)+k).

For etching the foresaid difference, the polysilicon 35 in the second reflecting region 36 is etched for a period of time. The period of time is (h−n×λ/4)/ER, wherein ER is λ/(4×Δt) derived from the time difference Δt between the two adjacent wave crest and the wave trough and the quarter coherence wavelength λ.

The height difference n×λ/4 is the relative height difference between the first reflecting region 36 and the second reflecting region 37. Hence, the height difference n×λ/4 is not influenced by the non-constant original height difference between the first reflecting region 36 and the second reflecting region 37. The difference (h−n×λ/4) is less than the selected height difference h. Therefore, the effect of the actual etching rate (ER) could be reduced. Furthermore, when the difference (h−n×λ/4) is less than λ/4, the etching rate effect on controlling the etching depth could be reduced to minimum.

In addition, the source of the coherence light could be a laser having an adjustable wavelength. Thus, the wavelength λ could be regulated to fit the condition of the selected height difference (h=n×λ/4).

When the amount n of the relative extreme values of the interference intensity is obtained, the etching step is stopped for accurately controlling the etching depth.

Certainly, the variant difference of the original height difference between the first reflecting region 36 and the second reflecting region 37 shown in FIG. 3(a) is not more than λ/4. Otherwise, some mistakes would occurr due to the mis-determination on the amount n of the relative extreme values.

While the invention has been described in terms of what are presently considered to be the most practical and preferred embodiments, it is to be understood that the invention need not be limited to the disclosed embodiment. On the contrary, it is intended to cover various modifications and similar arrangements included within the spirit and scope of the appended claims which are to be accorded with the broadest interpretation so as to encompass all such modifications and similar structures. Therefore, the above description and illustration should not be taken as limiting the scope of the present invention which is defined by the appended claims.

What is claimed is:

1. A method for controlling an etching depth in a semiconductor fabricating process, comprising steps of:
providing a substrate having a first reflecting region and a second reflecting region;
illuminating said first reflecting region and said second reflecting region with a coherence light having a wavelength λ to generate an interference;
performing a first etching on said second reflecting region to generate a height difference between said first reflecting region and said second reflecting region, wherein the interference intensity is changed with said first etching; and
performing a second etching on said second reflecting region for a specific period of time to make said etching depth as said height difference when said interference intensity is changed to a relative extreme value.

2. The method according to claim 1, wherein said relative extreme value is less than said height difference, wherein the difference between said relative extreme value and said height difference is one of a value equal to λ/4 and a value less than λ/4.

3. The method according to claim 1, wherein said substrate is a silicon substrate.

4. The method according to claim 1, wherein said first reflecting region and said second reflecting region are made of silicon and polysilicon, respectively.

5. The method according to claim 1, wherein said coherence light is emitted from a mercury lamp and a wavelength thereof is 2,537 angstrom.

6. The method according to claim 1, wherein said coherence light is a laser having an adjustable wavelength.

7. The method according to claim 1, wherein each of said first etching and said second etching is an anisotropic dry etching.

8. The method according to claim 1, wherein said relative extreme value is located at one of a wave crest and a wave trough of said interference.

9. The method according to claim 1, wherein said specific period of time is determined by steps of:
selecting two adjacent relative extreme values in said first etching and said second etching to obtain a time difference Δt, and obtaining etching rate (ER) as λ/(4×Δt); and
adding up a total number n of relative extreme values of said interference from beginning of said first and second etching to a time point which said relative extreme value is reached, and obtaining said height difference between said first reflecting region and said second reflecting region as n λ/4 and said period of time as (said height difference−n λ/4)/ER.

10. The method according to claim 1, wherein said first reflecting region and said second reflecting region are made of silicon and metal, respectively.

11. The method according to claim 1, wherein a variant difference of an original height difference between said first reflecting region and said second reflecting region is one of a value equal to λ/4 and a value less than λ/4.

12. A method for controlling an etching depth in a semiconductor fabricating process, comprising steps of:
providing a substrate having a first reflecting region and a second reflecting region;
performing an etching on said second reflecting region to generate a height difference between said first reflecting region and said second reflecting region;
selecting a coherence light having a wavelength λ to make said height difference be multiple of λ/4, and illuminating said first reflecting region and said second reflecting region with said coherence light to generate an interference, wherein the interference intensity is changed with said etching; and
stopping said etching performance to make said etching depth as said height difference when said interference intensity is changed to a relative extreme value.

13. The method according to claim 12, wherein said substrate is a silicon substrate.

14. The method according to claim 12, wherein said first reflecting region and said second reflecting region are made of silicon and polysilicon, respectively.

15. The method according to claim 12, wherein said coherence light is a laser having an adjustable wavelength.

16. The method according to claim 12, wherein said etching is an anisotropic dry etching.

17. The method according to claim 12, wherein said relative extreme value is located at one of a wave crest and a wave trough of said interference.

18. The method according to claim 12, wherein said etching performance is stopped when a total number of said relative extreme values of said interference are added up to n, and said height difference n λ/4 is obtained as said etching depth.

19. The method according to claim 12, wherein said first reflecting region and said second reflecting region are made of silicon and metal, respectively.

20. The method according to claim 12, wherein a variant difference of an original height difference between said first reflecting region and said second reflecting region is one of a value equal to λ/4 and a value less than λ/4.
